(19) United States
(12) Patent Application Publication
(10) Pub. No.: US 2006/0273396 A1
(43) Pub. Date: Dec. 7, 2006

(54) SEMICONDUCTOR DEVICE AND MANUFACTURING METHOD THEREOF

(75) Inventors: Yoshiharu Anda, Toyama (JP); Akiyoshi Tamura, Osaka (JP); Hirotada Taniuchi, Hyogo (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/383,561

(22) Filed: May 16, 2006

(30) Foreign Application Priority Data
Jun. 6, 2005 (JP) 2005/165998

(51) Int. Cl. H01L 27/12

(52) U.S. Cl. 257/350

(57) ABSTRACT

The present invention aims to provide a semiconductor device that can improve an element isolation breakdown voltage, which includes a semiconductor resistor using an InGaP layer as a semiconductor layer exposed on a surface. The present invention includes: an FET having a channel layer and a schottky layer which is made of undoped InGaP and is formed on the channel layer; and a semiconductor resistor having a part of the schottky layer and channel layer which are isolated from the FET by the element isolation region. The FET and semiconductor resistor are formed on a substrate, and the schottky layer is removed in the element isolation region.

### BACKGROUND OF THE INVENTION

(1) Field of the Invention

The present invention relates to a semiconductor device, particularly to an integrated circuit including a field-effect transistor and a semiconductor resistor, and the manufacturing method of the integrated circuit.

(2) Description of the Related Art

In recent years, a field-effect transistor (hereinafter referred to as FET) which uses a compound semiconductor including GaAs has widely been in use in wireless communications, and particularly as a power amplifier for a cellular phone terminal, an RF switch and the like. As such FET, a device having a superior high-frequency characteristic called a PHEMT (Pseudomorphic High Electron Mobility Transistor) is commonly used. In addition, a semiconductor device has been widely in practical use, such as a monolithic microwave integrated circuit (MMIC) in which an active element such as an FET and a passive element such as a semiconductor resistor, a metal resistor, and a capacitor are integrated. In this technical field, a manufacturing method with much less processes is in high demand as in other industries, and simplification of a process is also required.

Although an FET using AlGaAs as a schottky layer is common in a PHEMT, use of InGaP as a schottky layer, in which the surface level density is lower than that of AlGaAs is also considered. However, in this case, WSi and the like, which is a refractory metal, is used as a gate electrode in order to control interdiffusion of In included in InGaP and a material included in the gate electrode by heat. Such an example is described in Japanese Laid-Open Patent Application No 2004-260054 Publication.

In addition, current saturation characteristics can be improved by using InGaP as a surface material of a semiconductor resistor; therefore, the present inventors have filed a prior application, Japanese Patent Application No. 2004-280227.

In addition, concerning element isolation formed in a device using InGaP, as shown in Japanese Laid-Open Patent Application No. 2003-197558 Publication, it is reported that element isolation is formed by implanting boron ions as a common method.

FIG. 1A is a top view of a conventional semiconductor resistor using an InGaP layer as a semiconductor layer which is exposed on a surface. In addition, FIG. 1B is a cross sectional view of the semiconductor resistor (cross sectional view in X1-X1′ line of FIG. 1A). Furthermore, FIG. 1C is a cross sectional view of the semiconductor resistor (cross sectional view in Y1-Y1′ line of FIG. 1A).

In this semiconductor resistor, an epitaxial layer 109 is formed on a semi-insulating GaAs substrate 101, and the epitaxial layer 109 includes the following layers: a buffer layer 102; a channel layer 103 made of undoped-type InGaAs; a spacer layer 104 made of AlGaAs; a delta-doping layer 105; an AlGaAs layer 106; an InGaP schottky layer 107; and a contact layer 108 made of n-type GaAs.

An ohmic electrode 110, for example, made of an alloy of Au/Ge/Ni, is formed on the contact layer 108 arranged on both sides of the semiconductor resistor. Furthermore, the schottky layer 107 is exposed on a surface in the part other than the both sides of the semiconductor resistor so as to make resistance of the resistor high. Here, an element isolation region 112 is formed by implanting boron ions from the schottky layer 107. The top surface of this resistor is covered with an insulating film (not illustrated) made of SiN or SiO₂, and the device is protected with this insulating film.

Next, a method of manufacturing a conventional semiconductor resistor is described hereinafter. FIGS. 2A to 2D are cross sectional views showing a method of manufacturing the semiconductor resistor.

First, as shown in FIG. 2A, the following layers are sequentially formed on the semi-insulating GaAs substrate 101: the buffer layer 102; channel layer 103 made of undoped-type InGaAs; spacer layer 104 made of AlGaAs; delta-doping layer 105; AlGaAs layer 106; InGaP schottky layer 107; and contact layer 108 made of n-type GaAs. Here, the semiconductor layers from the buffer layer 102 to the contact layer 108 are collectively referred to as the epitaxial layer 109.

Next, as shown in FIG. 2B, a photoresist pattern 116 is formed on the epitaxial layer 109, and the part of the contact layer 108 which does not function as resistance is removed. Then, the element isolation region 112 is formed in the epitaxial layer 109, where the InGaP schottky layer 107 is exposed on a surface, by implanting boron ions.

Next, as shown in FIG. 2C, a photoresist pattern 120 is formed by patterning a photoresist mask so as to have an opening on the part of the contact layer 108, and dry etching or wet etching is selectively performed on the part of the contact layer 108 exposed in the opening, using the schottky layer 107 as a stopper layer so as to selectively etch the contact layer 108 exposed in the opening.

Finally, as shown in FIG. 2D, an ohmic electrode 110 is formed on the contact layer 108 by depositing, for example, an alloy of Au/Ge/Ni, using an evaporation method and the like and lifting it off. With this, the semiconductor resistor which is connectable with other devices via wiring is formed.

### SUMMARY OF THE INVENTION

In the case where element isolation is performed by a common ion-implantation for a semiconductor resistor which uses an InGaP layer as a semiconductor layer exposed on a surface, the following problem occurs.

FIG. 3 is a diagram showing a relationship between applied voltage and the leakage current in a semiconductor resistor having an element isolation region with 10 μm of an element isolation distance. FIG. 4 is a diagram showing a relationship between an element isolation breakdown voltage which is obtained by FIG. 3 and is indicated in the vertical axis, and an element isolation distance indicated in a horizontal axis.

As shown in the dashed line of FIG. 4, with a conventional element isolation method, the element isolation breakdown voltage reaches a saturation point in the case of a voltage equal to or less than 100V; therefore, it is hard to state that proper element isolation breakdown voltage including a surge breakdown voltage can be obtained.

Generally, in a switch MMIC for radio frequency, it is assumed that a pad which connects to external devices is connected to a gate electrode of an FET via a gate resistance made up of semiconductor resistors. In this case, a high element isolation breakdown voltage and a surge breakdown voltage are required.

Thus, the present invention is made for solving the aforementioned problem. In addition, the main object of the present invention is to provide a semiconductor device including a semiconductor resistor using an InGaP layer as a semiconductor layer exposed on a surface, which can improve an element isolation breakdown voltage.

In order to achieve the above object, the semiconductor device of the present invention includes: an active element having a channel layer and a schottky layer which is made of undoped InGaP and is formed on the channel layer; and a semiconductor resistor having a part of the schottky layer and channel layer which are isolated from the active element by an element isolation region, wherein the semiconductor resistor and active element are formed on a substrate, and the schottky layer is removed in the element isolation region. Here, it is desirable that the active element is a field-effect transistor. In addition, it is desirable that the schottky layer is removed in a non-conductive part which does not function as resistance of the semiconductor resistor. Furthermore, it is desirable that the element isolation region is formed by implanting boron ions.

According to this structure, as shown in FIG. 4 as a result of the invention, it is possible to realize a high element isolation breakdown voltage in a semiconductor device including a semiconductor resistor using an InGaP layer as a semiconductor layer exposed on a surface.

In addition, the present invention is a method of manufacturing a semiconductor device including an active element and a semiconductor resistor which are formed on a substrate, and the method includes: sequentially laminating on the substrate, a channel layer, a schottky layer made of undoped InGaP, and a contact layer; separating the contact layer into a first contact layer where the active element is formed and a second contact layer where the semiconductor resistor is formed, by removing a part of the contact layer to the extent that the schottky layer is exposed; removing the exposed schottky layer; and removing a part of the first contact layer and second contact layer simultaneously. Here, it is desirable that the active element is a field-effect transistor, and recess etching is performed on the first contact layer so as to form a gate electrode in the removing of the contact layer.

As this method of manufacturing the semiconductor device can etch the InGaP layer with fewer processes, it is possible to easily manufacture an FET using InGaP and a semiconductor resistor using InGaP on the same substrate, in which the FET and the resistor are properly isolated from each other.

As described above, according to the present invention, it is possible to form a semiconductor resistor, using an InGaP layer as a semiconductor layer exposed on a surface on the same substrate where an FET having a schottky layer made of InGaP is formed, as well as to realize a high element isolation breakdown voltage. As a result, the effect of surface level can be reduced, and cost of the device which drives and controls high frequency and high power can be reduced. Thus, this technology is useful, in particular, for a cellular phone terminal and the like.

### FURTHER INFORMATION ABOUT TECHNICAL BACKGROUND TO THIS APPLICATION

The disclosure of Japanese Patent Application No. 2005-165998 filed on Jun. 6, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a top view of a conventional semiconductor resistor of a semiconductor device.

FIG. 1B is a cross sectional view of the semiconductor resistor (cross sectional view in X1-X1′ line of FIG. 1A).

FIG. 1C is a cross sectional view of the semiconductor resistor (cross sectional view in Y1-Y1′ line of FIG. 1A).

FIG. 2A is a cross sectional view showing a method of manufacturing a semiconductor resistor of a conventional semiconductor device.

FIG. 2B is a cross sectional view showing a method of manufacturing the semiconductor resistor.

FIG. 2C is a cross sectional view showing a method of manufacturing the semiconductor resistor.

FIG. 2D is a cross sectional view showing a method of manufacturing the semiconductor resistor.

FIG. 3 is a diagram showing a relationship between applied voltage and the leakage current.

FIG. 4 is a diagram showing a relationship between an element isolation breakdown voltage and an element isolation distance.

FIG. 5A is a top view showing a structure of a semiconductor resistor in the semiconductor device according to the first embodiment of the present invention.

FIG. 5B is a cross sectional view of the semiconductor resistor (cross sectional view in X1-X1′ line of FIG. 5A).

FIG. 5C is a cross sectional view of the semiconductor resistor (cross sectional view in Y1-Y1′ line of FIG. 5A).

FIG. 6A is a cross sectional view of a semiconductor resistor showing a method of manufacturing a semiconductor device according to the first embodiment of the present invention.

FIG. 6B is a cross sectional view of the semiconductor resistor showing a method of manufacturing the semiconductor device.

FIG. 6C is a cross sectional view of the semiconductor resistor showing a method of manufacturing the semiconductor device.

FIG. 6D is a cross sectional view of the semiconductor resistor showing a method of manufacturing the semiconductor device.

FIG. 7A is a top view showing a structure of a semiconductor resistor and an FET in the semiconductor device according to the second embodiment of the present invention.

FIG. 7B is a cross sectional view showing the structure of the semiconductor resistor and FET (cross sectional view in X1-X1′ line of FIG. 7A).

FIG. 7C is a schematic circuit diagram of the semiconductor device.

FIG. 8A is a cross sectional view of a semiconductor device showing a method of manufacturing the semiconductor device according to the second embodiment of the present invention.

FIG. 8B is a cross sectional view of the semiconductor device showing a method of manufacturing the semiconductor device.

FIG. 8C is a cross sectional view of the semiconductor device showing a method of manufacturing the semiconductor device.

FIG. 8D is a cross sectional view of the semiconductor device showing a method of manufacturing the semiconductor device.

FIG. 8E is a cross sectional view of the semiconductor device showing a method of manufacturing the semiconductor device.

FIG. 8F is a cross sectional view of the semiconductor device showing a method of manufacturing the semiconductor device.

FIG. 8G is a cross sectional view of the semiconductor device showing a method of manufacturing the semiconductor device.

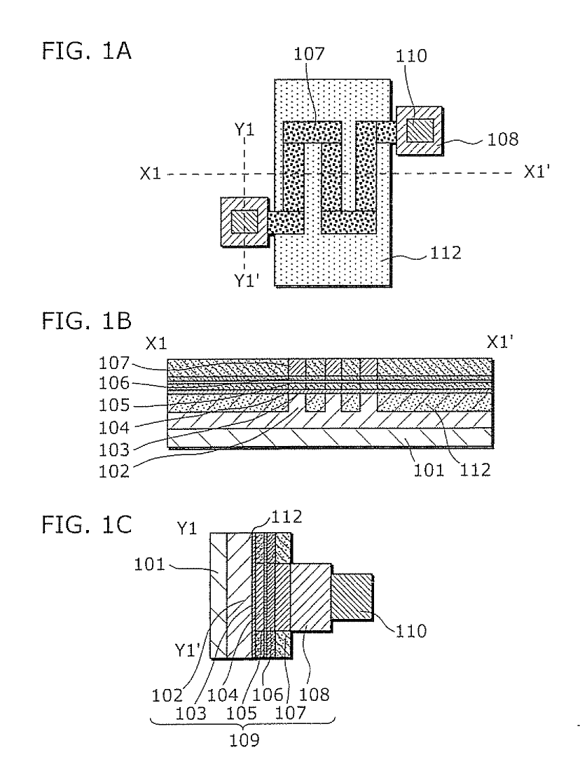

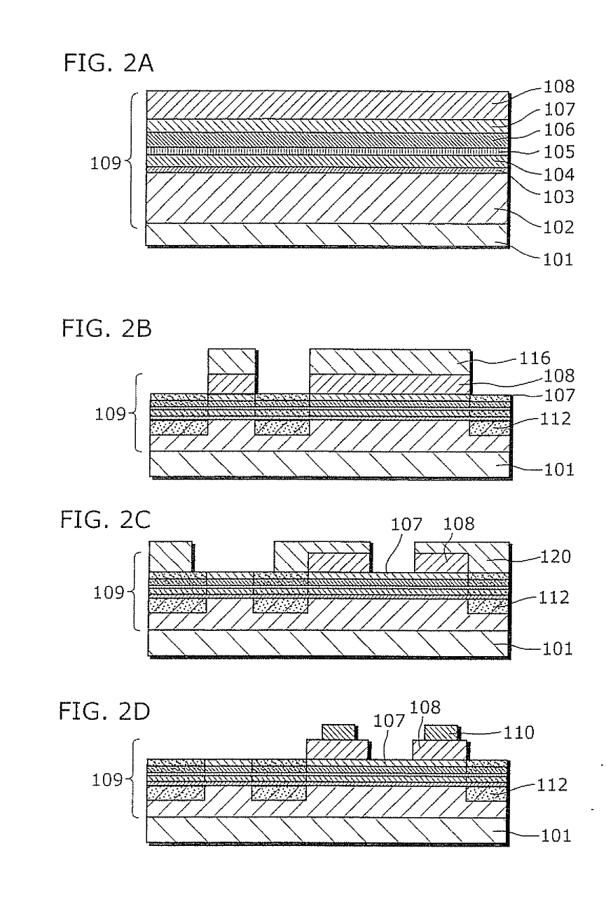

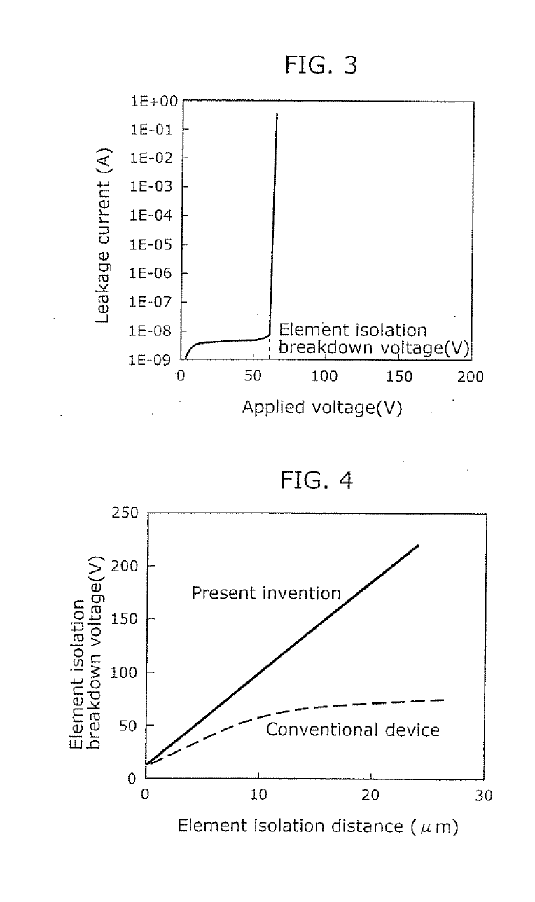

### DESCRIPTION OF THE PREFERRED EMBODIMENTS

The semiconductor device and the manufacturing method thereof in the embodiments of the present invention are described hereinafter with reference to the diagrams.

### First Embodiment

The first embodiment of the present invention is described hereinafter with reference to the diagrams.

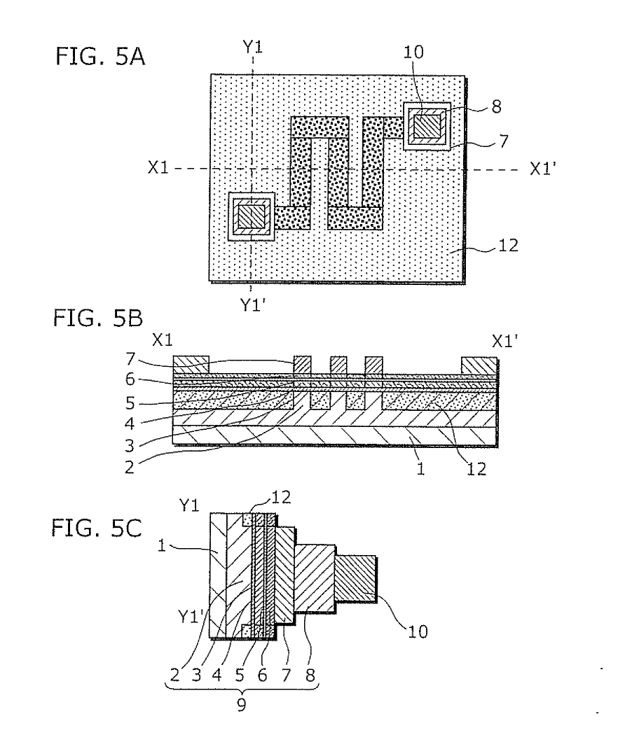

FIG. 5A is a top view showing a structure of a semiconductor resistor as a passive element in the semiconductor device according to the first embodiment of the present invention. In addition, FIG. 5B is a cross sectional view of the semiconductor resistor (cross sectional view in X1-X1′ line of FIG. 5A). Furthermore, FIG. 5C is a cross sectional view of the semiconductor resistor (cross sectional view in Y1-Y1′ line of FIG. 5A).

In this semiconductor resistor, the following layers are formed sequentially on a semi-insulating GaAs substrate 1 made of semi-insulating GaAs: a buffer layer 2 made of undoped GaAs with thickness of 1 μm and undoped AlGaAs with thickness of 100 nm in order to relax the lattice mismatching between an epitaxial layer which grows later and the semi-insulating GaAs substrate 1; a channel layer 3, made of undoped In_{0.2}Ga_{0.8}As with thickness of 20 nm, in which carriers are traveling; a spacer layer 4, made of undoped Al_{0.25}Ga_{0.75}As with thickness of 5 nm; a carrier supply layer 5 including only an atomic layer in which planar doping is performed so as to make a dose of Si, which is an n-type impurity ion, 5×10¹² cm⁻²; an undoped Al_{0.25}Ga_{0.75}As layer 6 with thickness of 20 nm; a schottky layer 7 made of undoped In_{0.48}Ga_{0.52}P with thickness of 10 nm; and a contact layer 8 made of n⁺-GaAs with thickness of 50 nm. Here, the semiconductor layers from the buffer layer 2 to the contact layer 8 are collectively referred to as an epitaxial layer 9.

An ohmic electrode 10, for example, made of an alloy of Au/Ge/Ni, is formed on the contact layer 108 arranged on both sides of the semiconductor resistor. Furthermore, the schottky layer 7 made of InGaP is exposed on a surface in a part other than the both sides of the semiconductor resistor so as to make resistance of the resistor high. The schottky layer 7 is removed in a part other than the part which functions as resistance. For example, the AlGaAs layer 6 is exposed on a surface. Then, an element isolation region 12 is formed by implanting boron ions from the AlGaAs layer 6. It should be noted that the semiconductor layer exposed on a surface in a part other than the part which functions as resistance is not limited to the AlGaAs layer 6. For example, the semiconductor layer may be the buffer layer 2 by performing further etching. The top surface of this resistor is covered with an insulating film (not illustrated) made of SiN or SiO₂, and the device is protected with this insulating film.

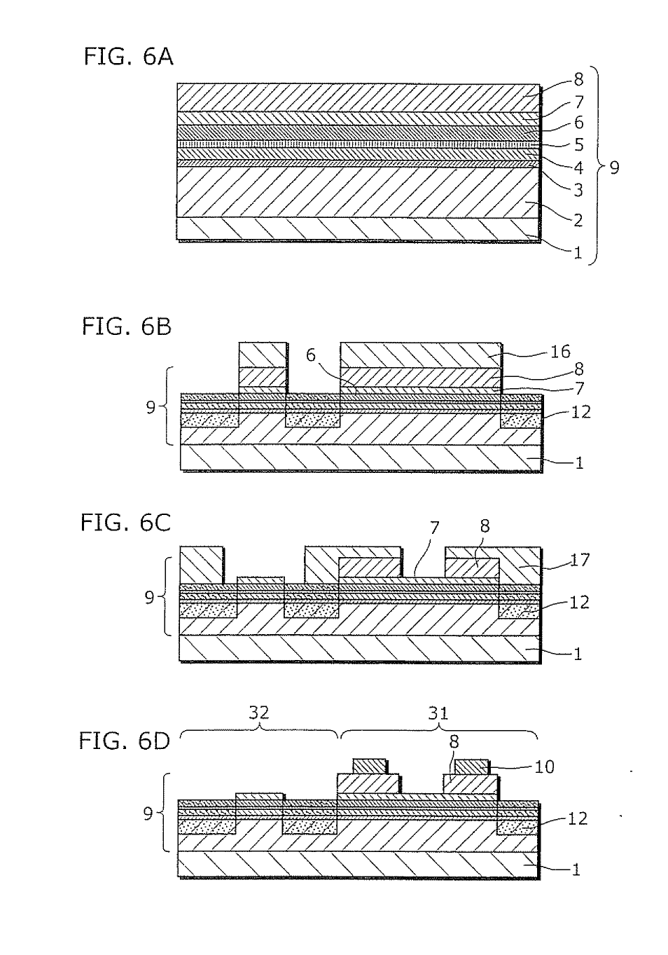

Next, a method of manufacturing a semiconductor device is described hereinafter with reference to the diagrams. FIGS. 6A to 6D are cross sectional views of a semiconductor resistor showing a method of manufacturing the semiconductor device.

First, as shown in FIG. 6A, the following layers are sequentially formed on the semi-insulating GaAs substrate 1: the buffer layer 2; channel layer 3 made of undoped-type InGaAs; spacer layer 4 made of AlGaAs; carrier supply layer 5; AlGaAs layer 6; InGaP schottky layer 7; and contact layer 8 made of n-type GaAs. Here, the semiconductor layers from the buffer layer 2 to the contact layer 8 are collectively referred to as the epitaxial layer 9.

Next, as shown in FIG. 6B, a photoresist pattern 16 is formed on the epitaxial layer 9, and a part of the contact layer 8 which does not function as resistance is removed. Then, selective etching is performed, for example, by HCL using the AlGaAs layer 6 as a stopper layer, on the InGaP schottky layer 7 which is exposed on a surface by the removing of the contact layer 8, so as to selectively etch the InGaP schottky layer 7. Next, for the layers beneath the AlGaAs layer 6, boron ions are implanted from the AlGaAs layer 6, so as to form the element isolation region 12 and perform element isolation.

Next, as shown in FIG. 6C, a photoresist pattern 17 is formed by patterning a photoresist mask so as to have an opening on the part of the contact layer 8, and dry etching or wet etching is selectively performed on the part of the contact layer 8 exposed in the opening, using the InGaP schottky layer 7 as a stopper layer so as to selectively etch the contact layer 8 exposed in the opening.

Finally, as shown in FIG. 6D, the ohmic electrode 10 is formed on the contact layer 8 by depositing, for example, an alloy of Au/Ge/Ni, using the evaporation method and the like and lifting it off. With this, an FET 31 and a semiconductor resistor 32 which is connectable with other devices via wiring are formed.

As described above, according to the semiconductor device of the present embodiment, the schottky layer 7 is removed in a non-conductive part which does not function as resistance. Thus, as shown in the solid line of FIG. 4, the element isolation breakdown voltage does not reach a saturation point with 100V; therefore, it is possible to realize a sufficiently high element isolation breakdown voltage. In other words, it is possible to realize a semiconductor device including a semiconductor resistor using InGaP layer as a semiconductor layer exposed on a surface, which improve an element isolation breakdown voltage.

### Second Embodiment

The second embodiment of the present invention is described hereinafter with reference to the diagrams.

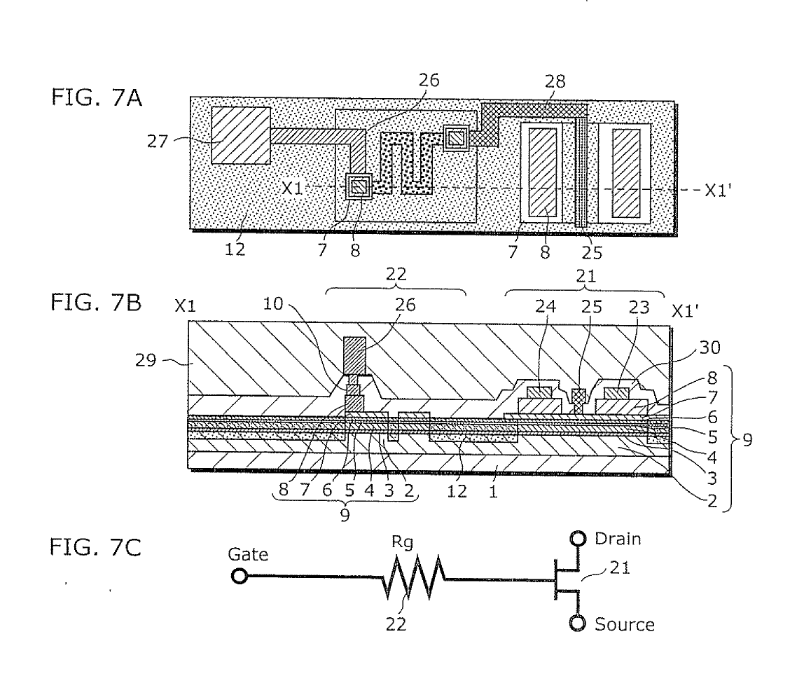

FIG. 7A is a top view showing a structure of a semiconductor resistor as a passive element and an FET as an active element in a semiconductor device according to the second embodiment of the present invention. In addition, FIG. 7B is a cross sectional view showing the structure of the semiconductor resistor and FET (cross sectional view in X1-X1′ line of FIG. 7A). Furthermore, FIG. 7C is a schematic circuit diagram of the semiconductor device.

This semiconductor device includes an FET 21 and a semiconductor resistor 22 which are formed on the same substrate.

In the FET 21, the following layers are sequentially formed on the semi-insulating GaAs substrate 1 made of semi-insulating GaAs: the buffer layer 2 made of undoped GaAs with thickness of 1 μm and undoped AlGaAs with thickness of 100 nm in order to relax the lattice mismatching between the epitaxial layer which grows later and the semi-insulating GaAs substrate 1; channel layer 3, made of undoped In_{0.2}Ga_{0.8}As with thickness of 20 nm, in which carriers are traveling; spacer layer 4, made of undoped Al_{0.25}Ga_{0.75}As with thickness of 5 nm; carrier supply layer 5 including only an atomic layer in which planar doping is performed so as to make a dose of Si, which is an n-type impurity ion, 5×10¹² cm⁻²; undoped Al_{0.25}Ga_{0.75}As layer 6 with thickness of 20 nm; schottky layer 7 made of undoped In_{0.48}Ga_{0.52}P with thickness of 10 nm; and contact layer 8 made of n⁺-GaAs with thickness of 50 nm. Here, the semiconductor layers from the buffer layer 2 to the contact layer 8 are collectively referred to as the epitaxial layer 9.

Here, a source electrode 23 and a drain electrode 24 which are ohmic electrodes are formed on the contact layer 8 of the epitaxial layer 9, and the top surface of the FET 21 and the semiconductor resistor 22 is covered with an interlayer insulating film 30 made of SiN or SiO₂. In addition, in a part where a gate electrode 25 is to be formed, the contact layer 8 is removed, and the opening part is formed. Furthermore, the gate electrode 25 which is a schottky electrode is formed on the InGaP schottky layer 7 exposed on a surface. This gate electrode 25 is, for example, made of WSi/Au. WSi included in the bottom layer of the gate electrode 25 is a material which has higher thermal reliability than InGaP which is included in the schottky layer 7. The element isolation region 12 is, for example, formed by an ion-implantation method, using such as boron ions. Here, the gate electrode 25 is connected to the semiconductor resistor 22 served as a gate resistance via wiring 28.

In this semiconductor resistor 22, the following layers are sequentially formed on the semi-insulating GaAs substrate 1 and are isolated from the FET 21: the buffer layer 2; the channel layer 3; the spacer layer 4; the carrier supply layer 5; the undoped Al_{0.25}Ga_{0.75}As layer 6; the schottky layer 7; and the contact layer 8. In an electroconductive first part which functions as resistance for the semiconductor resistor 22, the schottky layer 7 made of non-doped InGaP is exposed on a surface. With this, it is possible to realize a resistor with a favorable current saturation characteristic as well as high resistance. In addition, in a part which does not function as resistance, the non-electroconductive second part which is a part other than the part which functions as resistance for the semiconductor resistor 22, in other words, in the element isolation region 12 of the semiconductor resistor 22, the schottky layer 7 is removed by etching. For example, the AlGaAs layer 6 is exposed on a surface. In addition, the element isolation region 12 is formed by implanting boron ions. It should be noted that the semiconductor layer exposed on a surface in the second part is not limited to the AlGaAs layer 6. For example, the semiconductor layer may be the buffer layer 2 by performing further etching. The other end, which is not connected to the gate electrode 25 of the semiconductor resistor 22, is, for example, connected to a pad 27 for external connection via wiring 26.

These FET 21 and semiconductor resistor 22 are protected by the insulating film 29 made of SiN or SiO₂.

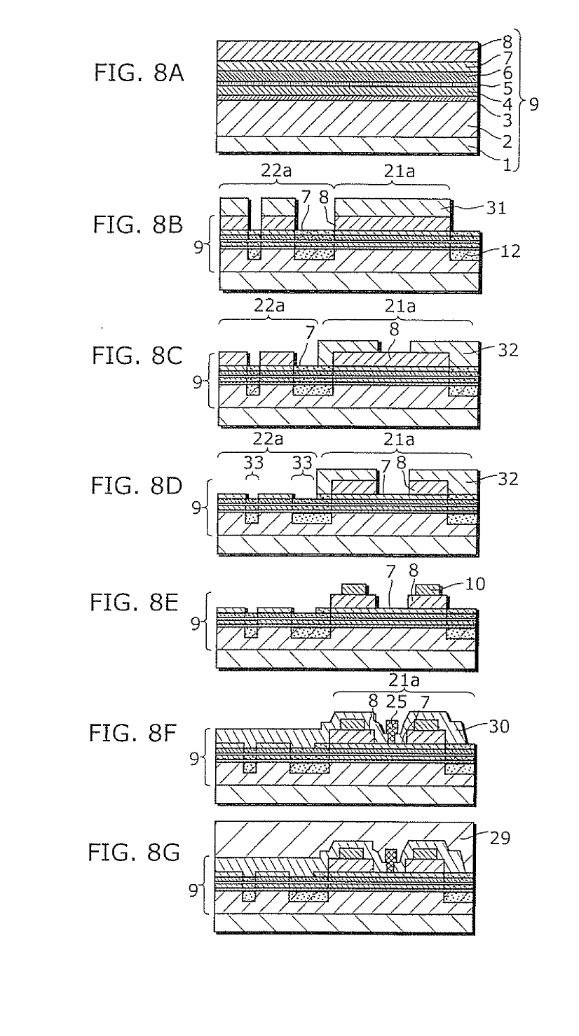

Next, the method of manufacturing the semiconductor device having the aforementioned structure is described hereinafter with reference to the diagrams. FIGS. 8A to 8G are cross sectional views of the semiconductor device showing the method of manufacturing a semiconductor device.

First, as shown in FIG. 8A, using a MOCVD method, MBE method or the like, the following layers are sequentially laminated on the semi-insulating GaAs substrate 1 through epitaxial growth: the buffer layer 2 made of GaAs and AlGaAs; the channel layer 3; the spacer layer 4; the carrier supply layer 5; the AlGaAs layer 6; the schottky layer 7 made of InGaP; and the contact layer 8 made of n⁺-GaAs. Here, the epitaxially grown semiconductor layers from the buffer layer 2 to the contact layer 8 are collectively referred to as the epitaxial layer 9.

Next, as shown in FIG. 8B, a photoresist pattern 31 is formed on the epitaxial layer 9. After protecting the desired position, for example, dry etching is performed on the contact layer 8 by using the schottky layer 7 as a stopper layer so as to selectively remove a part of the contact layer 8. With this, the contact layer 8 is separated into a first contact layer indicated by a section 21a where the FET 21 is formed, and a second contact layer indicated by a section 22a where the semiconductor resistor 22 is formed. The etching performed in this contact layer 8 is referred to as the first etching. Then, the element isolation region 12 is formed, for example, by implanting boron ions from the schottky layer 7 which is exposed on a surface by the first etching.

Next, as shown in FIG. 8C, a photoresist pattern 32 is formed by patterning the photoresist mask so as to have an opening part in a predetermined position.

Then, as shown in FIG. 8D, after removing the schottky layer 7 which is exposed on a surface by the first etching, recess etching is performed on the contact layer 8 in the section 21a where the FET 21 is formed, so as to form a gate electrode of the FET 21 by using the photoresist pattern 32. At the same time, etching is performed on the contact layer 8 in the section 22a where the semiconductor resistor 22 is formed. The dry etching performed in this contact layer 8 is referred to as the second etching. Here, the second etching includes the two-step etching processes. In other words, the steps are: the first step of performing etching in an InGaP layer with a condition of mainly performing the physical etching; and the second step of performing selective etching in a GaAs layer by using an InGaP layer as a stopper layer, so as to expose the InGaP layer. With this, it is possible to remove the InGaP layer in a portion 33 where the first etching and second etching overlap one another.

Moreover, it is clear that the same method can be used for the case where the contact layer 8 is made up of the laminated structure including an n⁺-GaAs layer and an n⁺-InGaAs layer which are generally used as non-alloy ohmic contact layers, aside from the case where the contact layer 8 is made up of a single n⁺-GaAs layer.

Next, as shown in FIG. 5E, the ohmic electrode 10 is formed on the contact layer 8 by depositing, for example, an alloy of Au/Ge/Ni, using an electron beam deposition method and the like, and lifting it off.

Then, as shown in FIG. 8F, after depositing 300 nm of the interlayer insulating film 30, which is made of SiN, on the FET 21 and the semiconductor resistor 22, a photoresist pattern is formed in which a part where the gate electrode 25 is to be formed is opened, and the interlayer insulating film 30 within the opening part is opened by dry etching. In this case, as damages may enter the opening part of the contact layer 8 in the section 21a by the dry etching, it is preferable to reduce the damages as much as possible. Next, a WSi/Au electrode is deposited on the entire wafer surface by a sputtering method, and a photoresist pattern is formed by patterning the photoresist to a predetermined shape. Then, the gate electrode 25 is formed by dry etching.

Finally, as shown in FIG. 8G, in order to protect the device, an insulating film 29 made of SiN or SiO₂ is formed so as to cover the entire FET 21 and the semiconductor resistor 22.

As described above, according to the semiconductor device of the present embodiment, the schottky layer 7 is removed in the non-conductive part which does not function as resistance. Therefore, likewise in the semiconductor device of the first embodiment, it is possible to realize a semiconductor device that can improve an element isolation breakdown voltage in the semiconductor device including a semiconductor resistor, using an InGaP layer as a semiconductor layer exposed on a surface.

In addition, as the method of manufacturing the semiconductor device of the present embodiment can etch the InGaP layer with fewer processes, it is possible to easily manufacture an FET using InGaP and a semiconductor resistor-using InGaP on the same substrate in which the FET and the resistor are properly isolated from each other

Moreover, according to the present invention, the FET is not limited to a PHEMT using a GaAs substrate, but includes every FET using an InGaP schottky layer. Furthermore, the present invention can also be applied to an FET using an InP substrate as well as an FET using InP as a schottky layer.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be applied to a semiconductor device and the manufacturing method, and particularly to a MMIC including a semiconductor resistor and an FET, and the manufacturing method of the MMIC.

What is claimed is:

1. A semiconductor device comprising:
an active element having a channel layer and a schottky layer which is made of undoped InGaP and is formed on the channel layer; and
a semiconductor resistor having a part of the schottky layer and channel layer which are isolated from said active element by an element isolation region,
wherein said semiconductor resistor and active element are formed on a substrate, and
the schottky layer is removed in the element isolation region.

2. The semiconductor device according to claim 1,
wherein said active element is a field-effect transistor.

3. The semiconductor device according to claim 2,
wherein the schottky layer is removed in a non-conductive part which does not function as resistance of said semiconductor resistor.

4. The semiconductor device according to claim 3,
wherein the element isolation region is formed by implanting boron ions.

5. The semiconductor device according to claim 2,
wherein the element isolation region is formed by implanting boron ions.

6. The semiconductor device according to claim 1,
wherein the schottky layer is removed in a non-conductive part which does not function as resistance of said semiconductor resistor.

7. The semiconductor device according to claim 1,
wherein the element isolation region is formed by implanting boron ions.

8. A method of manufacturing a semiconductor device including an active element and a semiconductor resistor which are formed on a substrate,
said method comprising:
sequentially laminating on the substrate, a channel layer, a schottky layer made of undoped InGaP, and a contact layer;
separating the contact layer into a first contact layer where the active element is formed and a second contact layer where the semiconductor resistor is formed, by removing a part of the contact layer to the extent that the schottky layer is exposed;
removing the exposed schottky layer; and
removing a part of the first contact layer and second contact layer simultaneously.

9. The method of manufacturing the semiconductor device according to claim 8,
wherein the active element is a field-effect transistor, and
in said removing of the contact layer, recess etching is performed on the first contact layer so as to form a gate electrode.
